(19) United States
(12) Patent Application Publication
(10) Pub. No.: US 2026/0052963 A1
(43) Pub. Date: Feb. 19, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Wei-Hao LIAO, Hsinchu (TW); Shau-Lin SHUE, Hsinchu (TW); Chih Wei LU, Hsinchu (TW); Hsin-Ping CHEN, Hsinchu (TW); Hsi-Wen TIEN, Hsinchu (TW); Wei-Chih WANG, Hsinchu (TW); Tzu-Hui WEI, Hsinchu (TW); Yung-Hsu WU, Hsinchu (TW); Li-Ling SU, Hsinchu (TW); Chia-Wei SU, Hsinchu (TW)

(73) Assignee: Taiwan Semiconductor Manufacturing Company, Ltd., Hsinchu (TW)

(21) Appl. No.: 18/804,346

(22) Filed: Aug. 14, 2024

(51) Int. Cl. H01L 21/768; H01L 23/528; H01L 23/535

(52) U.S. Cl. CPC H01L 21/76805; H01L 21/76816; H01L 21/76895; H01L 23/5283; H01L 23/535

(57) ABSTRACT

A semiconductor device includes a conductive feature part, a dielectric structure and a metal layer. The dielectric structure is formed over the conductive feature part. The dielectric structure includes a first dielectric layer and a second dielectric layer stacked on each other. The first dielectric layer and the second dielectric layer include different dielectric materials. The metal layer is disposed in the first dielectric layer and the second dielectric layer. The bottom surface of the metal layer is electrically connected to the conductive feature part, and the top surface of the metal layer is coplanar with the top surface of the dielectric structure. The bottom surface and the top surface of the metal layer have profiles of different sizes.

### BACKGROUND

The semiconductor integrated circuit (IC) industry has experienced rapid growth. Technological advances in IC materials and design have produced continuous improvements in generations of ICs. Each generation has smaller and more complex circuits than the previous generation. However, these advances have increased the complexity of processing and manufacturing ICs.

Since the feature sizes continue to decrease, fabrication processes continue to become more difficult to perform. Thus, there is a challenge to form reliable semiconductor devices with smaller and smaller sizes. For example, t he distances between via-to-drain (VD) and via-to-gate (VG) are closer and closer in the advanced nodes, and the critical dimension (CD) of VD and VG are smaller and smaller. Therefore, to achieve high performance IC, the higher resistance due to the smaller VD/VG contact area to BEOL metal became a critical issue.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A to 7A are respectively schematic cross-sectional views of a semiconductor device on the X-Z plane according to an embodiment of the present disclosure.

FIGS. 1B to 7B are respectively schematic top views of a semiconductor device on the X-Y plane according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

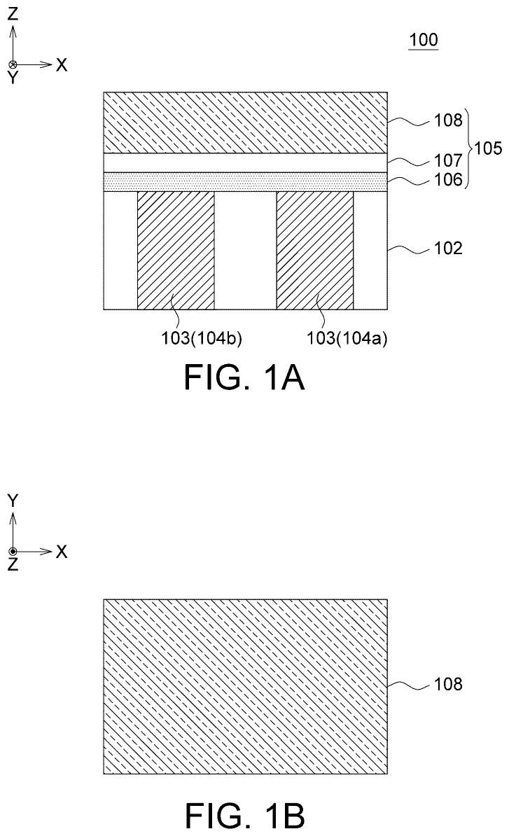

FIGS. 1A to 7A are respectively schematic cross-sectional view of a manufacturing method of a semiconductor device 100 on the X-Z plane according to an embodiment of the present disclosure. FIGS. 1B to 7B are respectively schematic top views of a manufacturing method of the semiconductor device 100 on the X-Y plane according to an embodiment of the present disclosure.

IC manufacturing processes can generally be divided into three categories: front-end-of-line (FEOL) process, middle-end-of-line (MEOL) process, and back-end-of-line (BEOL) process. FEOL process generally encompasses processes related to the manufacture of IC devices such as transistors. For example, FEOL process may include forming isolation structures for isolating IC devices, gate structures, and forming source and drain structures (also referred to as a source/drain structure) of a transistor. MEOL generally encompasses processes related to the fabrication of connection structures (also known as contacts or plugs) that connect to conductive feature parts (or conductive areas) of IC devices. For example, MEOL process may include forming a connection structure connected to a gate structure and a connection structure connected to a source/drain structure. BEOL process generally covers processes related to the fabrication of multi-layer interconnect (MLI) structures that electrically connect IC devices and connection structures manufactured by FEOL and MEOL processes. Therefore, the operation of the IC device can be realized. As mentioned above, process scaling has increased the complexity of processing and manufacturing ICs. For example, in some comparison methods, ruthenium (Ru) (which has a smaller resistivity) is used to form the connection structure formed by MEOL in order to reduce the plug contact resistance, but the connection structure containing Ru has presented yield and cost challenges, this is because the connection structure becomes more compact as the size of IC components continues to shrink.

Referring to FIGS. 1A and 1B, a dielectric structure 105 is formed over a semiconductor substrate 102 and a conductive feature part 103. The dielectric structure 105 includes a first dielectric layer 107 and a second dielectric layer 108 stacked on each other. The first dielectric layer 107 and the second dielectric layer 108 include different dielectric materials.

In one embodiment, the semiconductor substrate 102 may be a silicon substrate, silicon on an insulating layer, or other semiconductor materials. The dielectric structure 105 may be dielectric layers composed of multiple materials covering the semiconductor substrate 102, for example, a silicon oxide layer, a silicon nitride layer, silicon nitride carbide, a low dielectric coefficient (LK) material layer, ultra-low dielectric coefficient (ULK) material layer or any combination of the above materials. The semiconductor substrate 102 may include a conductive feature part 103 disposed therein. In some embodiments, the conductive feature part 103 may be a FEOL component, such as the metal gate or the source/drain region. In some embodiments, the conductive feature part 103 may be a MEOL component, such as a contact of a connecting structure. In other embodiments, the conductive feature part 103 may be a BEOL component, such as a metal wire.

In some embodiments, substrate 102 includes silicon. Alternatively or additionally, the substrate 102 includes: another elemental semiconductor, such as germanium; a compound semiconductor, such as silicon carbide, gallium arsenide, gallium phosphide, indium phosphide, indium arsenide and/or indium antimonide; an alloy semiconductor, such as silicon germanium (SiGe), GaAsP, AlInAs, AlGaAs, GaInAs, GaInP and/or GaInAsP; or combinations thereof. In some embodiments, the substrate 102 includes one or more Group III-V materials, one or more Group II-IV materials, or a combination thereof. In some embodiments, the substrate 102 is a semiconductor-on-insulator substrate, such as a silicon on insulator (SOI) substrate, a silicon germanium on insulator (SGOI) substrate, or a germanium on insulator (GOI) substrate. The semiconductor-on-insulator substrates may be fabricated using separation of implanted oxygen (SIMOX), wafer bonding, and/or other suitable methods. The substrate 102 may include various doped regions (not shown) configured according to design requirements of a device, such as p-type doped regions, n-type doped regions, or combinations thereof. The P-type doped region (e.g., p-type well) includes a p-type dopant, such as boron, indium, another p-type dopant, or a combination thereof. The N-type doped region (e.g., n-type well) includes an n-type dopant, such as phosphorus, arsenic, another n-type dopant, or a combination thereof. In some implementations, the substrate 102 includes doped regions formed using a combination of p-type dopants and n-type dopants. Various doped regions may be directly formed on and/or in the substrate 102, such as providing a p-well structure, an n-well structure, a double-well structure, a protruding structure, or a combination thereof. An ion implantation process, a diffusion process, and/or another suitable doping process may be performed to form various doped regions.

The conductive feature part 103 may be placed over the substrate 102, such as gate structure. In some embodiments, one or more gate structures may interpose a source/drain region, with a channel region defined between the source/drain regions. In some embodiments, a gate structure is formed over a fin structure. In some embodiments, the metal gate structure includes a gate dielectric layer and a gate electrode. A gate dielectric layer may be placed over the substrate 102, and a gate electrode is placed on the gate dielectric layer. The gate dielectric layer includes a dielectric material such as silicon oxide, a high-k material, another suitable dielectric material, or a combination thereof. High-k materials generally refer to dielectric materials with a high dielectric constant (for example, a dielectric constant greater than the dielectric constant of silicon oxide (k≈3.9)). Exemplary high-k materials include hafnium, aluminum, zirconium, lanthanum, tantalum, titanium, iridium, oxygen, nitrogen, another suitable component, or a combination thereof. In some embodiments, the gate dielectric layer includes a multi-layer structure, such as an interfacial layer (IL) (e.g., including silicon oxide) and a high-k layer (e.g., including HfO₂, HfSiO, HfSiON, HfTaO, HfTiO, HfZrO, ZrO₂, Al₂O₃, HfO₂—Al₂O₃, TiO₂, Ta₂O₅, La₂O₃, Y₂O₃), another suitable high dielectric coefficient material or a combination thereof.

The gate electrode contains a conductive material. In some implementations, the gate electrode includes multiple layers, such as one or more work function metal layers and gap fill metal layers. The work function metal layer includes a conductive material, such as an n-type work function material and/or a p-type work function material, tuned to have a desired work function, such as an n-type work function or a p-type work function. P-type work function materials include TiN, TaN, Ru, Mo, Al, WN, ZrSi₂, MoSi₂, TaSi₂, NiSi₂, WN, another p-type work function material, or a combination thereof. N-type work function materials include Ti, Al, Ag, Mn, Zr, TiAl, TiAlC, TaC, TaCN, TaSiN, TaAl, TaAlC, TiAlN, another n-type work function material, or a combination thereof. The gap fill metal layer may include a suitable conductive material such as Al, W and/or Cu.

In some embodiments, the conductive feature part 103 may be source/drain regions of the semiconductor device 100 including epitaxial structures. For example, a semiconductor material is epitaxially grown on the substrate 102 to form an epitaxial source/drain structure over a source/drain region of the substrate 102. Thus, the gate structure, the epitaxial source/drain structure, and a channel region defined between the epitaxial source/drain structures form a device, such as a transistor. In some embodiments, the epitaxial source/drain structure may surround the source/drain region of a fin structure. In some embodiments, an epitaxial source/drain structure may replace part of the fin structure. The epitaxial source/drain structure is doped with n-type dopants and/or p-type dopants. In some embodiments where the transistor is configured as an n-type device (e.g., with an n-channel), the epitaxial source/drain structure may include doped with phosphorus, another n-type dopant, or a silicon-containing epitaxial layer or a silicon carbide-containing epitaxial layer of a combination thereof (for example, forming a Si:P epitaxial layer or a Si:C:P epitaxial layer). In alternative embodiments in which the transistor is configured as a p-type device (e.g., with a p-channel), the epitaxial source/drain structure may include doped with boron, another p-type dopant, or a combination of silicon-germanium epitaxial layers (for example, forming a Si:Ge:B epitaxial layer). In some embodiments, the epitaxial source/drain structure includes materials and/or dopants that achieve desired tensile stress and/or compressive stress in the channel region.

As shown in FIG. 1A, the dielectric structure 105 can cover the substrate 102 and the conductive feature part 103 (such as the metal drain (MD) 104b and the metal gate (MG) 104a). In some embodiments, dielectric structure 105 may be referred to as an inter-layer dielectric (ILD) layer. In some embodiments, dielectric structure 105 may be referred to as an inter-layer dielectric (ILD) layer or an inter-metal dielectric (IMD) layer.

In some embodiments, before forming the first dielectric layer 107, a contact etch stop layer (CESL) 106 may be formed on the substrate 102. The contact etch stop layer (CESL) 106 may include silicon nitride, silicon oxynitride, and the like. The first dielectric layer 107 is formed on the contact etch stop layer (CESL) 106. The first dielectric layer 107 may include silicon oxide. The second dielectric layer 108 is formed on the first dielectric layer 107. The second dielectric layer 108 may include silicon carbide, silicon oxycarbide, and the like. The contact etch stop layer (CESL) 106 has a thickness of approximately 10 to 50Å. The thickness of the first dielectric layer 107 is approximately 50 to 300 Å, and the thickness of the second dielectric layer 108 is approximately 300 to 700 Å.

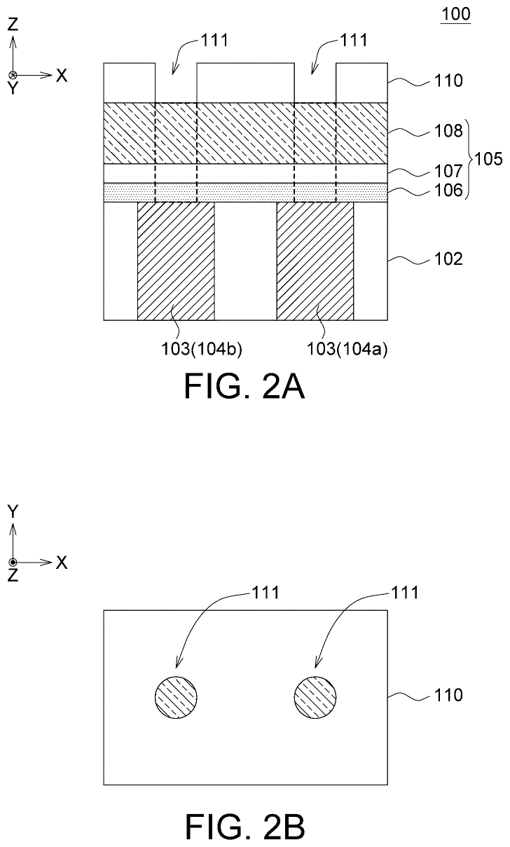

Referring to FIGS. 2A and 2B, a patterned photoresist layer 110 is formed on the dielectric structure 105 to expose part of the dielectric structure 105 in the opening 111 of the patterned photoresist layer 110. The opening size of the patterned photoresist layer 110 is used to define the aperture size of the dielectric structure 105 to be etched.

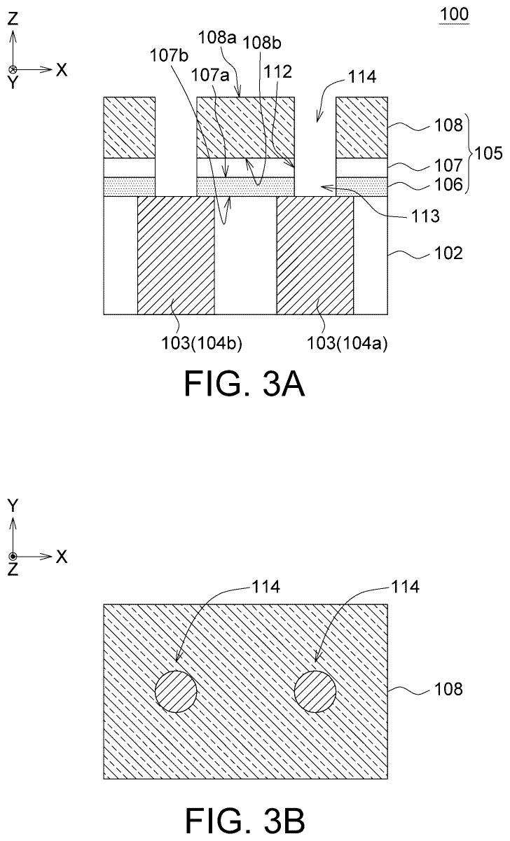

Referring to FIGS. 3A and 3B, the dielectric structure 105 is etched to form a first opening 112 in the first dielectric layer 107 and a second opening 114 in the second dielectric layer 108 respectively. In addition, the contact etch stop layer (CESL) 106 is etched to form a third opening 113 in the contact etch stop layer (CESL) 106. In some embodiments, the first opening 112, the second opening 114 and the third opening 113 penetrate the dielectric structure 105 from a top surface to a bottom surface of the dielectric structure 105. Therefore, a portion of the conductive feature part 103 is exposed through the first opening 112, the second opening 114 and the third opening 113. The first opening 112, the second opening 114 and the third opening 113 may be formed using a lithography operation using a masking technique and an anisotropic etching operation (e.g., plasma etching or reactive ion etching), but the disclosure is not limited thereto.

In some embodiments, the anisotropic etching conditions include the following: power: 100-2000 W/bias: 0-1200 kV, and the reaction gas includes at least one of HBr, Cl₂, H₂, CH₄, N₂, He, Ne, Kr, CF₄, CHF₃, CH₃F, CH₂F₂, C₄F₈, C₄F₆, SF₆, N₂, O₂ and Ar. In some embodiments, the dielectric structure 105 and contact etch stop layer (CESL) 106 are processed via a first anisotropic etching, the first opening 112, the second opening 114 and the third opening 113 may have profiles with consistent opening sizes, and the opening patterns are, for example, circular or other patterns. That is to say, the first opening 112, the second opening 114 and the third opening 113 may have circular profiles with consistent opening sizes. In one embodiment, the first opening 112 has a circular profile at the top surface 107a of the first dielectric layer 107, and the first opening 112 has a circular profile at the bottom surface 107b of the first dielectric layer 107.

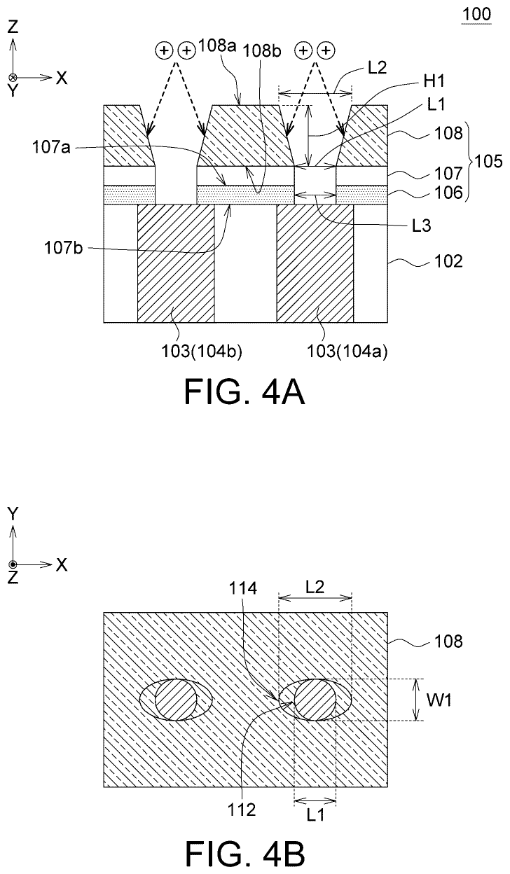

Referring to FIG. 4A and FIG. 4B, the dielectric structure 105 is partially etched to enlarge the top size of the opening, so that the second opening 114 and the first opening 112 have profiles of different opening sizes. In some embodiments, the second dielectric layer 108 may use a masking technique and anisotropic etching (e.g., plasma etching or reactive ion etching) to increase the opening size L2 of the second opening 114 and the first dielectric layer 107 is selected to have a high etch selectivity ratio with the second dielectric layer 108 to prevent the opening size L1 of the first opening 112 and the opening size L3 of the third opening 113 from increasing. In some embodiments, the etch selectivity ratio of the second dielectric layer 108 relative to the first dielectric layer 107 may be greater than 5, such as greater than 7 or higher. In addition, the etch selectivity ratio of the second dielectric layer 108 relative to the contact etch stop layer (CESL) 107 may be greater than 5, such as greater than 7 or higher.

As shown in FIG. 4B, the second opening 114 has an elliptical profile at the top surface 108a of the second dielectric layer 108, and the elliptical profile includes a major axis dimension L1 and a minor axis dimension W1. The major axis dimension L1 is greater than the minor axis dimension W1. That is, the second dielectric layer 108 increases the size of the second opening 114 in a first direction (such as the X-axis) through anisotropic etching (such as plasma etching or reactive ion etching), but the size of the second opening 114 in the second direction (e.g., Y-axis) perpendicular to the first direction remains unchanged. In addition, the second opening 114 has a circular profile at the bottom surface 108b of the second dielectric layer 108, which has the same opening size as that of the first opening 112.

When the plasma or ion beam performs local etching and opening expansion on the second dielectric layer 108, the etching reaction of the plasma or ion beam on the first dielectric layer 107 is weaker than the etching reaction of the plasma or ion beam on the second dielectric layer 108, so that the first dielectric layer 107 can protect the contact etch stop layer (CESL) 106 at the bottom of the first dielectric layer 107 from being bombarded by plasma or ion beam to prevent under-etching problems, thereby the leakage problem between the subsequent metal layer 116 to the neighboring conductive feature part 103 can be improved.

In some embodiments, the anisotropic etching and opening expansion of the second dielectric layer 108 includes the following: power: 100-1000 W/bias: 0-12 kV, and the reaction gas includes at least one of materials selected from He, Ne, Kr, Ar, CF₄, CHF₃, CH₃F, CH₂F₂, C₄F₈, C₄F₆, SF₆ and O₂. In some embodiments, the ratio between the major axis dimension L1 and the minor axis dimension W1 may be greater than 1.5 and less than 3. In addition, the difference between the major axis dimension L1 and the minor axis dimension W1 may be between 5 and 10 nm. In some embodiments, the ratio between the major axis dimension L1 and the thickness H1 of the second dielectric layer 108 may be greater than 2 and less than 5.

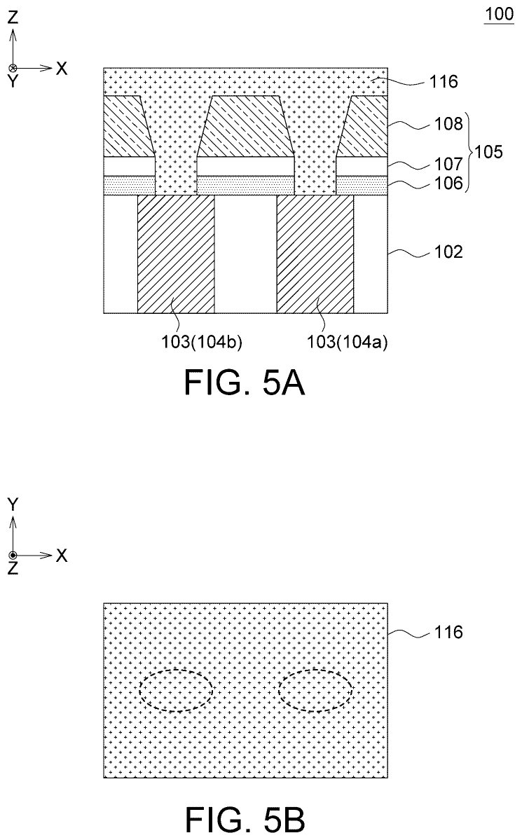

Referring to FIGS. 5A and 5B, a metal layer 116 (or connection structure) is formed in the first opening 112, the second opening 114 and the third opening 113, and the bottom surface 116b of the metal layer 116 is electrically connected to the conductive feature part 103, so that the conductive feature part 103 can be connected to a back-end-of-line (BEOL) interconnection structure through the metal layer 116. The metal layer 116 may be referred to as a metal-to-device (MD), metal-to-drain (MD) or metal-to-gate (MG) contact, which generally refers to a contact to the source/drain region or a contact to the gate structure. In some embodiments, metal layer 116 may be formed without a liner layer, a barrier, a seed layer, or any interposer. Therefore, in these embodiments, the metal layer 116 may be in contact with the dielectric structure 105, but the present disclosure is not limited thereto.

The metal layer 116 can be formed on the dielectric structure 105 and recessed in the etched opening through a deposition process, such as an atomic layer deposition (ALD) process, an epitaxial growth process, a low pressure chemical vapor deposition (LPCVD) process and/or a plasma enhanced chemical vapor deposition (PECVD) process. The metal layer 116 may be selected from the group consisting of cobalt (Co), nickel (Ni), Plumbum (Pb), gold (Au), rhenium (Re), iridium (Ir), titanium, and hafnium (Hf), platinum (Pt), ruthenium (Ru), aluminum (Al) and any combination of the above to form a group of metal elements.

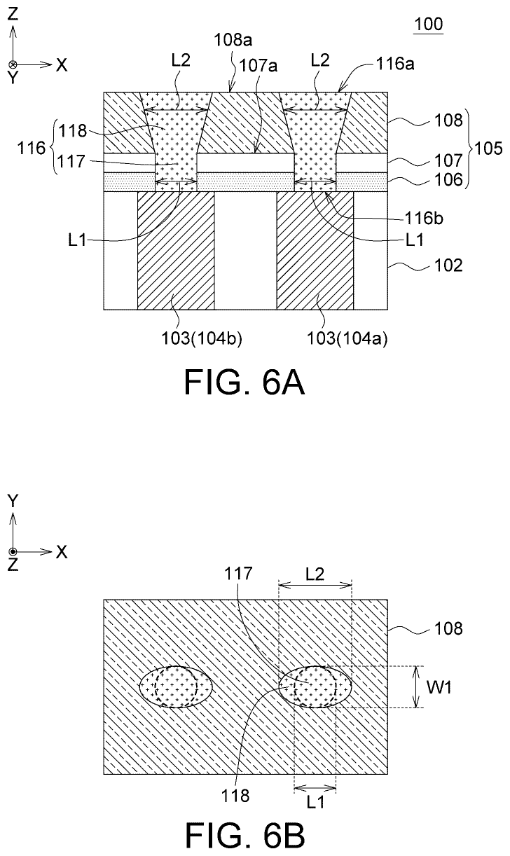

Referring to FIGS. 6A and 6B, a portion of the metal layer 116 is removed to expose the top surface 108a of the dielectric structure 105 and the top surface 116a of the metal layer 116. The area of the bottom surface 116b of the metal layer 116 is smaller than the area of the top surface 116a of the metal layer 116. In some embodiments, the metal layer 116 is planarized, and the metal layer 116 located above the second dielectric layer 108 is removed by chemical mechanical polishing (CMP), leaving only the metal layer 116 embedded in the first dielectric layer 107 and the second dielectric layer 108 and the contact etch stop layer (CESL) 106. After the planarization process, the top surface 108a of the dielectric structure 105 is coplanar with the top surface 116a of the metal layer 116. In one embodiment, the top surface 116a of the metal layer 116 has an elliptical profile, and the elliptical profile includes a major axis dimension L1 and a minor axis dimension W1. The bottom surface 116b of the metal layer 116 has a circular profile.

In some embodiments, the interconnection structure includes a first dielectric layer 107, a second dielectric layer 108 and a metal layer 116. The metal layer 116 is disposed in the first dielectric layer 107 and the second dielectric layer 108. The metal layer 116 includes a first component 117 located in the first dielectric layer 107 and a second component 118 located in the second dielectric layer 108. The first component 117 is connected to the second component 118. The size of the second component 118 in a first direction (e.g., X-axis) is greater than the size of the second component 118 in a second direction (e.g., Y-axis) perpendicular to the first direction. As shown in FIGS. 6A and 6B, the second component 118 has an elliptical profile at the top surface 108a of the second dielectric layer 108, and the second component 118 has a circular shape at the bottom surface 108b of the second dielectric layer 108. The first component 117 has a circular profile at the top surface 107a of the first dielectric layer 107, and the first component 117 has a circular profile at the bottom surface 107b of the first dielectric layer 107. The size of the second component 118 in the second direction (e.g., Y-axis) is equal to the size of the circular profile at the top surface 107a of the first dielectric layer 107.

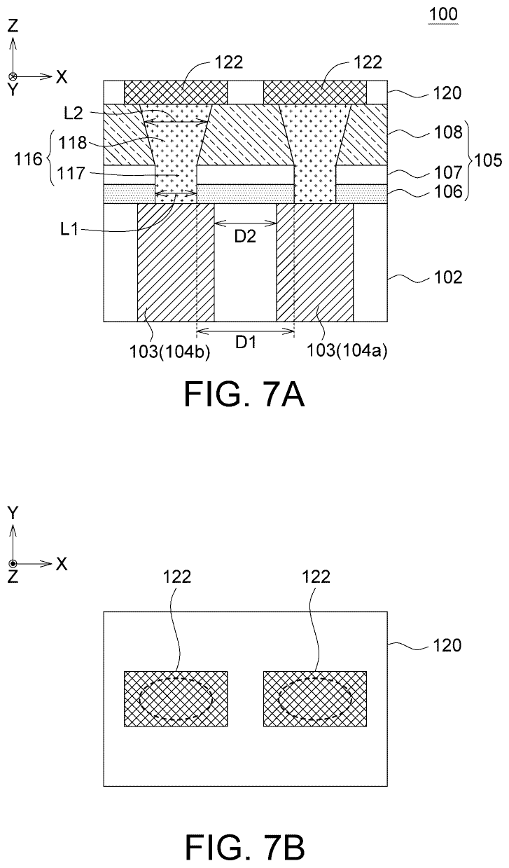

Referring to FIGS. 7A and 7B, in some embodiments, a third dielectric layer 120 may be formed over the dielectric structure 105 and the metal layer 116. Another conductive feature part 122 may be formed in the third dielectric layer 120. The conductive feature part 122 may be coupled to metal layer 116. The conductive feature part 122 is connected to top surface 116a of metal layer 116. Since the contact area between the conductive feature part 122 and the top surface 116a of the metal layer 116 is greater than the contact area between the conductive feature part 103 and the bottom surface 116b of the metal layer 116, the resistance between the conductive feature part 103 and the top surface 116a of the metal layer 116 is relatively smaller than that between the conductive feature part 103 and the bottom surface 116b of the metal layer 116. In addition, since the second dielectric layer 108 increases the opening size in the major axis direction through etching, when the metal layer 116 fills the second opening 114, the metal layer 116 has a better filling rate to avoid the formation of voids or defects in the second opening 114.

The third dielectric layer 120 may be an ILD layer or an IMD layer. In some embodiments, the ILD layer or IMD layer may include materials as mentioned above. In some embodiments, the conductive feature part 122 may be a MEOL component, such as a contact of a connection structure. In other embodiments, the conductive feature part 122 may be a BEOL component, such as a metal wire.

In addition, in order to avoid leakage problems between the metal layer 116 and the neighboring conductive feature part 103, the bottom surface 116b of the metal layer 116 is reduced in size (nearly a circular profile), so that the area of the bottom surface 116b of the metal layer 116 is smaller than the area of the top surface 116a of the metal layer 116. Due to the reduced profile of the bottom surface 116b of the metal layer 116, the distance between the metal layer 116 and the neighboring conductive feature part 103 can be increased. As shown in FIG. 7A, the contact area between the bottom surface 116b of the metal layer 116 and the corresponding conductive feature part 103 is reduced, so that the distance D1 between two adjacent metal layers 116 is greater than the distance D2 between two adjacent conductive feature parts 103. The conductive feature part 103 may be a FEOL component of the metal gate or the source/drain region, to avoid leakage between the metal gate 104a and the adjacent connection structures, and to prevent leakage between the metal drain 104b and the adjacent connection structures.

The present disclosure is directed to a semiconductor device and a manufacturing method thereof. The first and second dielectric layers have high etch selectivity ratio to elongate critical dimension of the second opening in unidirectional etching by reactive ion beam, and the top-view shape of the second opening was changed from circle to oval. This approach could increase the contact area between MEOL contact and BEOL metal, and the contact resistance can be effectively reduced. This approach (bilayer ILD) also could constrain via bottom critical dimension to prevent leakage between VD to MG (or VG to MD) from lateral etch on CESL during directional ion beam etch.

According to some embodiments of the present disclosure, a method of manufacturing a semiconductor device includes the following steps. A dielectric structure is formed above a substrate and a conductive feature part. The dielectric structure includes a first dielectric layer and a second dielectric layer stacked on each other. The first dielectric layer and the second dielectric layer include different dielectric materials. The dielectric structure is etched to form a first opening in the first dielectric layer and a second opening in the second dielectric layer respectively, and the first opening is connected to the second opening. The conductive feature part is exposed, and the first opening and the second opening have profiles of different opening sizes. A metal layer is formed in the first opening and the second opening, and the bottom surface of the metal layer is electrically connected to the conductive feature part. A portion of the metal layer is removed to expose the top surface of the dielectric structure and the top surface of the metal layer, wherein the area of the bottom surface of the metal layer is smaller than the area of the top surface of the metal layer.

According to some embodiments of the present disclosure, a semiconductor device includes a conductive feature part, a dielectric structure and a metal layer. The dielectric structure is formed over the conductive feature part. The dielectric structure includes a first dielectric layer and a second dielectric layer stacked on each other. The first dielectric layer and the second dielectric layer include different dielectric materials. The metal layer is disposed in the first dielectric layer and the second dielectric layer. The bottom surface of the metal layer is electrically connected to the conductive feature part, and the top surface of the metal layer is coplanar with the top surface of the dielectric structure. The bottom surface of the metal layer and the top surface of the metal layer have profiles of different sizes.

According to some embodiments of the present disclosure, an interconnection structure includes a first dielectric layer, a second dielectric layer and a metal layer. The second dielectric layer is disposed on the first dielectric layer. The metal layer is disposed in the first dielectric layer and the second dielectric layer, the metal layer includes a first component located in the first dielectric layer and a second component located in the second dielectric layer, the first component is connected to the second component, and a size of the second component in a first direction is greater than a size of the second component in a second direction perpendicular to the first direction.

The foregoing profiles features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, comprising:
forming a dielectric structure over a substrate and a conductive feature part, the dielectric structure comprising a first dielectric layer and a second dielectric layer stacked on each other, and the first dielectric layer and the second dielectric layer having different dielectric materials;
etching the dielectric structure to form a first opening in the first dielectric layer and a second opening in the second dielectric layer respectively, the first opening being connected to the second opening, and the conductive feature part being exposed from the first and second openings, and the first opening and the second opening have profiles of different opening sizes;
forming a metal layer in the first opening and the second opening, and a bottom surface of the metal layer is electrically connected to the conductive feature part; and
removing a portion of the metal layer to expose a top surface of the dielectric structure and a top surface of the metal layer, wherein an area of the bottom surface of the metal layer is smaller than an area of the top surface of the metal layer.

2. The method of claim 1, further comprising forming a contact etch stop layer on the substrate before forming the first and second dielectric layers, the first dielectric layer covering the contact etch stop layer.

3. The method of claim 1, wherein forming the second opening in the second dielectric layer includes increasing a size of the second opening in a first direction through anisotropic etching so that the size of the second opening in the first direction is greater than a size of the second opening in a second direction perpendicular to the first direction.

4. The method of claim 3, wherein an etch selectivity ratio of the second dielectric layer relative to the first dielectric layer is greater than 5.

5. The method of claim 3, wherein the second opening has an elliptical profile at a top surface of the second dielectric layer, and the second opening has a circular profile at a bottom surface of the second dielectric layer.

6. The method of claim 3, wherein the first opening has a circular profile at a top surface of the first dielectric layer, and the first opening has a circular profile at a bottom surface of the first dielectric layer, the size of the second opening in the second direction is equal to the size of the circular profile.

7. A semiconductor device, comprising:
a conductive feature part;
a dielectric structure formed over the conductive feature part, the dielectric structure comprising a first dielectric layer and a second dielectric layer stacked on each other, the first dielectric layer and the second dielectric layer having different dielectric materials; and
a metal layer disposed in the first dielectric layer and the second dielectric layer, a bottom surface of the metal layer is electrically connected to the conductive feature part, and a top surface of the metal layer is coplanar with a top surface of the dielectric structure, the bottom surface and the top surface of the metal layer have profiles of different sizes.

8. The semiconductor device of claim 7, wherein the conductive feature part is a front-end-of-line (FEOL) or middle-end-of-line (MEOL) component.

9. The semiconductor device of claim 7, wherein the dielectric structure is an inter-layer dielectric (ILD) layer or an inter-metal dielectric (IMD) layer.

10. The semiconductor device of claim 7, further comprising a contact etch stop layer, and the first dielectric layer covering the contact etch stop layer.

11. The semiconductor device of claim 7, wherein the first dielectric layer has a first opening, the second dielectric layer has a second opening, and the contact etch stop layer has a third opening, the first opening, the second opening and the third opening are connected, and the first opening and the third opening have circular profiles with the same opening size.

12. The semiconductor device of claim 11, wherein a size of the second opening in a first direction is gr eater than a size of the second opening in a second direction perpendicular to the first direction.

13. The semiconductor device of claim 11, wherein an etch selectivity ratio of the second dielectric layer relative to the first dielectric layer is greater than 5.

14. The semiconductor device of claim 11, wherein the second opening has an elliptical profile at a top surface of the second dielectric layer, and the second opening has a circular profile at a bottom surface of the second dielectric layer.

15. The semiconductor device of claim 11, wherein the first opening has a circular profile at a top surface of the first dielectric layer, and the first opening has a circular profile at a bottom surface of the first dielectric layer, and the size of the second opening in the second direction is equal to a size of the circular profile.

16. An interconnection structure, comprising:
a first dielectric layer;
a second dielectric layer disposed on the first dielectric layer;
a metal layer disposed in the first dielectric layer and the second dielectric layer, the metal layer comprising a first component located in the first dielectric layer and a second component located in the second dielectric layer, the first component being connected to the second component, wherein a size of the second component in a first direction is greater than a size of the second component in a second direction perpendicular to the first direction.

17. The interconnection structure of claim 16, wherein the second component has an elliptical profile at a top surface of the second dielectric layer, and the second component has a circular profile at a bottom surface of the second dielectric layer.

18. The interconnection structure of claim 17, wherein the first component has a circular profile at a top surface of the first dielectric layer, and the first component has a circular profile at a bottom surface of the first dielectric layer.

19. The interconnection structure of claim 18, wherein the size of the second component in the second direction is equal to a size of the circular profile at the top surface of the first dielectric layer.

20. The interconnection structure of claim 16, wherein an area of the bottom surface of the metal layer is smaller than an area of the top surface of the metal layer.
